(19) United States
(12) Patent Application Publication
(10) Pub. No.: US 2020/0049873 A1
(43) Pub. Date: Feb. 13, 2020

(54) OPTICAL MODULE

(71) Applicant: Hisense Broadband Multimedia Technologies Co., Ltd., Qingdao (CN)

(72) Inventor: Long ZHENG, Qingdao (CN)

(73) Assignee: Hisense Broadband Multimedia Technologies Co., Ltd., Qingdao (CN)

(21) Appl. No.: 16/567,884

(22) Filed: Sep. 11, 2019

Related U.S. Application Data
(63) Continuation of application No. PCT/CN2019/099466, filed on Aug. 6, 2019.

(30) Foreign Application Priority Data
Aug. 8, 2018 (CN) 201810899205.6

(51) Int. Cl. F21V 8/00; H05K 1/18; H05K 7/14; H05K 9/00; H05K 1/02

(52) U.S. Cl. CPC G02B 6/0005; H05K 1/18; H05K 7/1427; H05K 2201/10121; H05K 1/0274; H05K 2201/10113; H05K 9/0007

(57) ABSTRACT

The present disclosure describes an optical module. The optical module includes a housing comprising a first portion, a second portion, and protrusions, and the protrusions are configured to enclose the first portion to isolate the first portion from the second portion. The optical module includes a circuit board disposed inside the housing, the circuit board comprising a first area, a second area, and a metal strip attaching to the protrusions. The optical module further includes an indicator light configured to emit light and a laser driving chip. The first area of the circuit board is electrically connected to the indicator light to supply power to the indicator light. The second area of the circuit board is electrically connected to the laser driving chip. The metal strip encloses the first area to isolate the first area from the second area.

### CROSS-REFERENCE TO RELATED APPLICATIONS

This application is a continuation of International Application No. PCT/CN2019/099466, filed on Aug. 6, 2019, which claims the priority of Chinese Patent Application No. 201810899205.6 filed on Aug. 8, 2018, both of which are hereby incorporated by reference in their entireties.

### TECHNICAL FIELD

The embodiments of the present disclosure relate to the field of optical module, and more particularly to an optical module.

### BACKGROUND

An optical module usually includes a housing and a circuit board disposed inside the housing. To facilitate a user to understand the operating status of an optical module, indicator lights needs to be disposed in the optical module.

### SUMMARY

The embodiments of the present disclosure provide an optical module, which improves the security performance of the optical module.

In a first aspect, some embodiments of the present disclosure are directed to an optical module comprising: a housing, a circuit board, an indicator light, and a laser driving chip, where the circuit board is disposed inside the housing, and light emitted by the indicator light propagates to the outside of the housing; where the circuit board includes a first area, a second area and a metal strip, the metal strip encloses the first area to isolate the first area from the second area, the first area is configured to supply power to the indicator light, the second area is electrically connected to the laser driving chip; the housing includes a first portion, a second portion, and protrusions, the protrusions enclose the first portion to isolate the first portion from the second portion, and the protrusions and the metal strip are attached.

The present disclosure describes an optical module. The optical module includes a housing comprising a first portion, a second portion, and protrusions, and the protrusions are configured to enclose the first portion to isolate the first portion from the second portion. The optical module includes a circuit board disposed inside the housing, the circuit board comprising a first area, a second area, and a metal strip attaching to the protrusions. The optical module further includes an indicator light configured to emit light and a laser driving chip. The first area of the circuit board is electrically connected to the indicator light to supply power to the indicator light. The second area of the circuit board is electrically connected to the laser driving chip. The metal strip encloses the first area to isolate the first area from the second area.

The present disclosure also describes a method for preparing an optical module. The method includes providing a housing comprising a first portion, a second portion, and protrusions, the protrusions configured to enclose the first portion and isolate the first portion from the second portion. The method includes disposing a circuit board inside the housing, the circuit board comprising a first area, a second area, and a metal strip attaching to the protrusions. The method includes electrically connecting the first area of the circuit board to an indicator light configured to emit light to supply power to the indicator light. The method includes electrically connecting the second area of the circuit board to a laser driving chip. The metal strip encloses the first area and isolates the first area from the second area.

### BRIEF DESCRIPTION OF THE DRAWINGS

In order to more clearly illustrate the technical solutions in the embodiments of the present disclosure, the drawings required in the description of the embodiments will be briefly described below. It is obvious that the drawings in the following description are some embodiments of the present disclosure, and for those skilled in the art, other drawings can also be obtained according to these drawings without paying inventive efforts.

FIG. 1 is a schematic structural diagram of an optical module according to some embodiments of the present disclosure;

FIG. 2 is a schematic structural diagram 1 of a circuit board according to some embodiments of the present disclosure;

FIG. 3 is a schematic structural diagram 2 of a circuit board according to some embodiments of the present disclosure;

FIG. 4 is a schematic structural diagram 3 of a circuit board according to some embodiments of the present disclosure;

FIG. 5 is a schematic structural diagram 4 of a circuit board according to some embodiments of the present disclosure;

FIG. 6 is a schematic structural diagram of an upper housing according to some embodiments of the present disclosure;

FIG. 7 is a schematic structural diagram of a lower housing according to some embodiments of the present disclosure;

FIG. 8 is a schematic structural diagram of an upper housing and a circuit board according to some embodiments of the present disclosure.

11: housing;
12: circuit board;
13: indicator light;
14: laser driving chip;
15: light guide;
16: conductive connector;
111: upper housing;
112: lower housing;
121: first area;
122: second area;
123: mental strip;
171: first protrusion;
172: second protrusion;
181: third protrusion;
182: fourth protrusion;
1811: first notch;
1821: second notch.

### DETAILED DESCRIPTION OF THE EMBODIMENTS

In order to make the objects, technical solutions and advantages of some embodiments of the present disclosure clearer, the technical solutions in the embodiments of the present disclosure will be clearly and completely described with reference to the drawings in the embodiments of the present disclosure. Obviously, the embodiments described are part of the embodiments of the present disclosure, and not all of the embodiments. All other embodiments obtained by those skilled in the art based on the embodiments of the present disclosure without paying inventive efforts are within the scope of protection of the present disclosure.

In an optical module, a light-emitting component is disposed inside a housing, and one end of the light-emitting component is connected to a circuit board. The circuit board controls the light-emitting component to be illuminated, and the other end of the light-emitting component extends to a light outlet on the housing to form an indicator light at the light outlet so that the circuit board is connected to the light outlet. In the circuit board, the components such as a laser driving chip, a gold finger and the like are also disposed. The electromagnetic waves are generated during the working process of the components such as the laser driving chip and the gold finger and the like, and the electromagnetic waves can leak to the outside of the housing through the light outlet, thereby the leaked electromagnetic waves causes interference to other electronic devices in the vicinity of the optical module, resulting in poor security performance of the optical module.

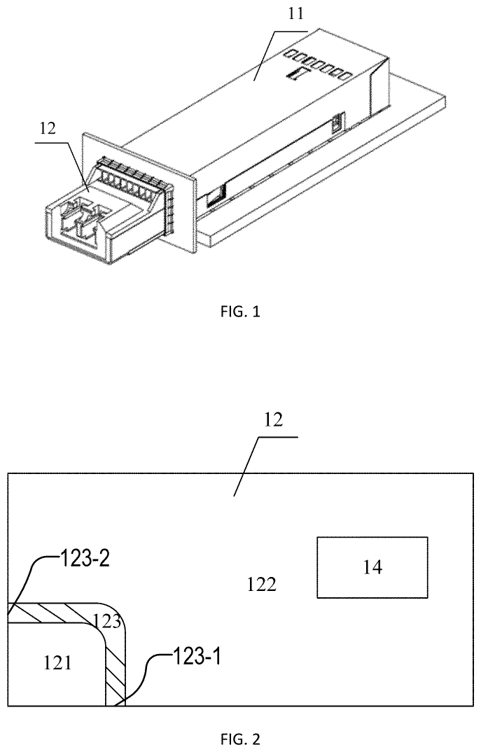

FIG. 1 is a schematic structural diagram of an optical module according to some embodiments of the present disclosure. Referring to FIG. 1, the optical module includes: a housing 11, a circuit board 12, an indicator light 13 and a laser driving chip 14, where the circuit board 12 is disposed inside the housing 11, and light emitted by the indicator light 13 propagates to the outside of the housing 11.

Optionally, the housing is made of metal material such that the housing can isolate electromagnetic waves generated by components such as the laser driving chip in the circuit board.

In order to facilitate understanding the present application, the structure of the circuit board and the housing is described in detail below.

The circuit board shown in some embodiments of the present disclosure includes a first area, a second area and a metal strip, where the metal strip encloses the first area to isolate the first area from the second area, the first area is configured to supply power to the indicator light, and the second area is electrically connected to the laser driving chip.

Optionally, the first area is located in an edge area of the circuit board or in an intermediate area of the circuit board. Specifically, further discussion is made with reference to the embodiments shown in FIG. 2 to FIG. 5.

FIG. 2 is a schematic structural diagram 1 of a circuit board according to some embodiments of the present disclosure. With reference to FIG. 2, the circuit board 12 includes a first area 121, a second area 122 and a metal strip 123. The first area 121 is located at an edge area of the circuit board 12. The metal strip may include a first end 123-1 and a second end 123-2. The first end 123-1 may be a starting end, and the second end 123-2 may be an ending end. The first and second ends of the metal strip 123 are respectively connected to the edge of the circuit board 12 to enclose the first area 121. The first area 121 is configured to supply power to the indicator light 13, and the second area 122 is electrically connected to the laser driving chip 14.

Optionally, the first area 121 includes a top corner of the circuit board.

With reference to FIG. 2, the metal strip 123 is L-shaped, a first end 123-1 of the metal strip 123 is connected to a first edge of the circuit board 12. The first edge of the circuit board may be a lower edge of the circuit board. A second end 123-2 of the metal strip 123 is connected to a second edge of the circuit board 12. The second edge of the circuit board may be a left edge of the circuit board. The metal strip 123, the underneath of the left edge the circuit board 12, and the left of the lower edge of the circuit board 12 may be enclosed into a closed first area 121. In the present disclosure, a directional term (e.g., left, right, top, low, lower, etc.) may be used to refer to a certain position or direction in the drawings, which is merely as an exemplary illustration and is not a limitation to the present disclosure.

Optionally, the metal strip 123 is in other shapes. For example, the metal strip 123 may be arc, linear, and the like. In actual application scenarios, the shape of the metal strip 123 may be designed according to actual needs, which is not specifically limited in the embodiments of the present disclosure.

The laser driving chip 14 is configured to control the laser used in the optical module to be illuminated. During the working process of the driving chip 14, electromagnetic waves are generated.

Optionally, the laser driving chip 14 is electrically connected to the second area 122 by means of soldering, or the laser driving chip 14 is electrically connected to the second area 122 through a wire. In actual application process, the manner in which the laser driving chip 14 and the second area 122 are electrically connected may be configured according to actual needs. The embodiments of the present disclosure are not limited with regard of this matter.

Optionally, the components such as an integrated circuit (IC), a gold finger, and the like are disposed in the second area 122.

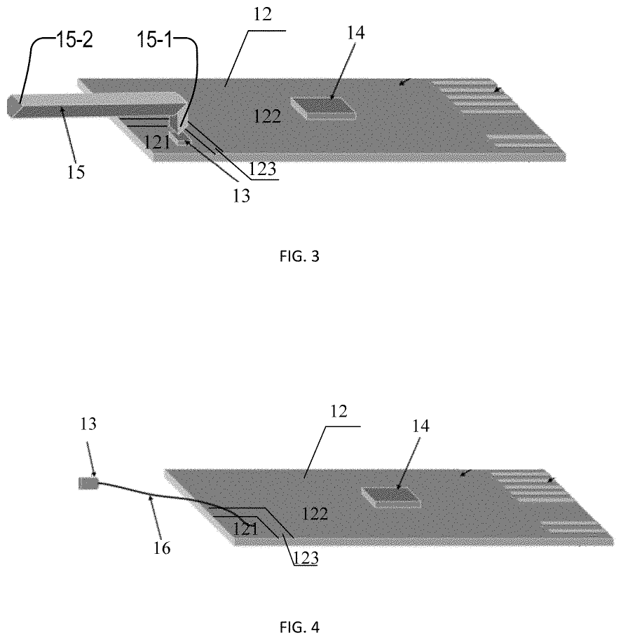

Hereinafter, the manner in which the first area 121 supplies power to the indicator light 13 is described in detail with reference to the schematic structural diagram of the circuit board of FIG. 3 to FIG. 4.

FIG. 3 is a schematic structural diagram 2 of a circuit board according to some embodiments of the present disclosure. Referring to FIG. 3, the indicator light 13 is disposed in the first area 121. A light guide 15 may include a first end 15-1 and a second end 15-2. The first end 15-1 of the light guide 15 receives light emitted by the indicator light 13 and the second end 15-2 of the light guide 15 extends to a light outlet of the housing 11.

Optionally, the indicator light 13 is disposed in the first area 121 by means of soldering, and the indicator light 13 is connected to the first area 121 by a wire, a flexible printed circuit (FPC) and the like.

Optionally, the distance between one end of the light guide 15 and the indicator light 13 is less than a first preset distance, so that the light guide 15 can receive the light emitted by the indicator light 13.

Optionally, the first preset distance may be 0.1 mm and the like.

Of course, in actual application process, the first preset distance is designed according to actual needs. The embodiments of the present disclosure are not limited with regard of this matter.

FIG. 4 is a schematic structural diagram 3 of a circuit board according to some embodiments of the present disclosure. Referring to FIG. 4, the indicator light 13 is disposed at a light outlet of the housing 11, and the indicator light 13 is electrically connected to the first area 121 through a conductive connector 16.

Optionally, the conductive connector 16 is a wire, an FPC, and the like.

In the embodiments shown in FIG. 3 to FIG. 4, the first area is located at an edge area of the circuit board, such that the light guide or the conductive connector extends to the light outlet of the housing through the edge of the circuit board, and the light guide or the conductive connector does not need to cross the second area, thereby the first area can be better enclosed.

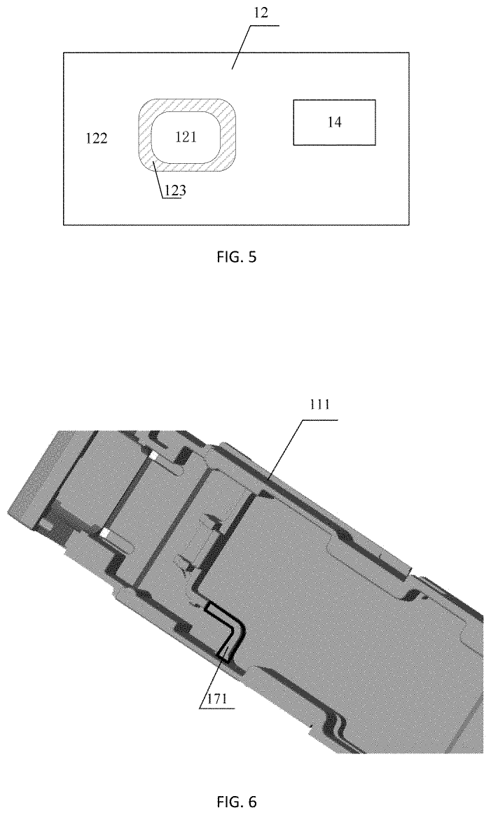

FIG. 5 is a schematic structural diagram 4 of a circuit board according to some embodiments of the present disclosure. Referring to FIG. 5, the first area 121 is located at an intermediate area of the circuit board 12, and the metal strip 123 is in a closed curve to enclose the first area 121.

With reference to FIG. 5, the second area 122 is an area of the circuit board other than the first area 121 and the metal strip 123, and the second area 122 is electrically connected to the laser driving chip 14.

Optionally, the metal strip 123 is of other shapes. For example, the metal strip 123 is rectangular, circular, irregular, and the like. In actual application process, the shape of the metal strip 123 may be designed according to actual needs. The embodiments of the present disclosure are not limited with regard of this matter.

The housing shown in the embodiments of the present disclosure includes a first portion, a second portion, and protrusions, where the protrusions enclose the first portion to isolate the first portion from the second portion, and the protrusions and the metal strip are attached. For example, a protrusion and a corresponding metal strip may have matching contact surfaces against each other; and when the protrusion and the corresponding metal strip is attached, the matching contact surfaces may contact each other to electrically connect to each other and decrease leakage of electromagnetic waves to the outside of the housing. In one implementation, the matching contact surfaces may be both flat surfaces. In another implementation, one of the matching contact surfaces may be a concave surface and the other of the matching contact surfaces may be a convex surface. In another implementation, one of the matching contact surfaces may include a saw-shape cross-section shape and the other of the matching contact surfaces may include a matching saw-shape cross-section shape.

Optionally, the shape of the protrusions is similar to or matches the shape of the metal strip so that the protrusions and the metal strip can be attached.

Optionally, the housing includes an upper housing and a lower housing, and the upper housing and the lower housing are fastened to form the housing. The upper housing and the lower housing are generally symmetrically designed so that the upper housing and the lower housing can be fastened. Correspondingly, the protrusions include a first protrusion and a second protrusion, and the first protrusion is disposed on the upper housing, and the second protrusion is disposed on the lower housing. The metal strip includes a first metal strip and a second metal strip, and the first metal strip is disposed on an upper surface of the circuit board, and the second metal strip is disposed on a lower surface of the circuit board, where the first protrusion and the first metal strip are attached, and the second protrusion and the second metal strip are attached.

Optionally, the shape of the first metal strip and the shape of the second metal strip is similar or matched.

Optionally, the first metal strip and the second metal strip are oppositely disposed on the circuit.

Optionally, the first metal strip and the second metal strip penetrates the circuit board.

Optionally, the shape of the first protrusion and the shape of the first metal strip are similar or matched, such that the first protrusion and the first metal strip can be attached.

Optionally, the shape of the second protrusion and the shape of the second metal strip are similar or matched, such that the second protrusion and the second metal strip can be attached.

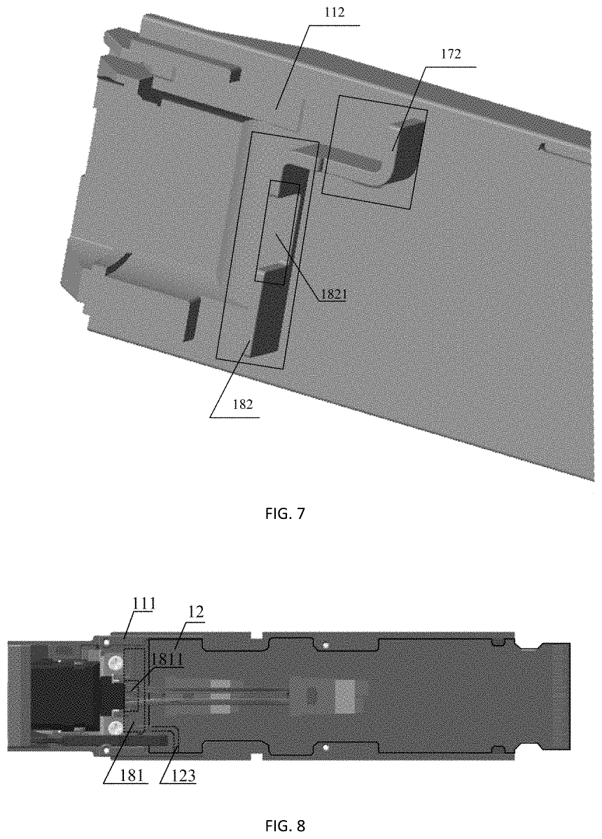

Hereinafter, the upper housing and the lower housing are described in detail respectively with reference to FIG. 6 to FIG. 7.

FIG. 6 is a schematic structural diagram of an upper housing according to some embodiments of the present disclosure. Referring to FIG. 6, the first protrusion 171 of the protrusions is disposed on the upper housing 111.

With reference to FIG. 6, in the upper housing 111, the left side of the first protrusion 171 is the first portion, and the right side of the first protrusion 171 is the second portion, and the first protrusion 171 isolates the first portion from the second portion.

It should be noted that the upper housing shown in FIG. 6 is described in which the first area of the circuit board is located at a position of the edge area of the circuit board. When the first area is located in the intermediate area of the circuit board, the position and shape of the first protrusion 171 in the upper housing 111 are also adaptively changed so that the first protrusion 171 and the first metal strip are attached.

FIG. 7 is a schematic structural diagram of a lower housing according to some embodiments of the present disclosure. Referring to FIG. 7, the second protrusion 172 of the protrusions is disposed on the lower housing 112.

With reference to FIG. 7, in the lower housing 112, the left side of the second protrusion 172 is the first portion, and the right side of the second protrusion 172 is the second portion, and the second protrusion 172 isolates the first portion from the second portion.

Optionally, a fourth protrusion 182 is disposed on the lower housing 112.

Optionally, a second notch 1821 is disposed on the fourth protrusion 182, and the second notch 1821 is designed to enable an optical fiber in the circuit board 12 to pass through.

Correspondingly, a third protrusion is disposed on the upper housing 111, and a first notch is disposed on the third protrusion, and the first notch is designed to enable an optical fiber in the circuit board 12 to pass through.

It should be noted that, in actual application process, a notch is disposed only on the fourth protrusion or the third protrusion, or notches may be simultaneously disposed on the fourth protrusion and the third protrusion. The embodiments of the present disclosure are not limited with regard of this matter.

Optionally, in the upper housing, when the height of the first protrusion is the same as the height of the third protrusion, the height of the fourth protrusion is greater than the height of the second protrusion, and the height difference between the fourth protrusion and the second protrusion is equal to the thickness of the circuit board. Because a circuit board needs to be disposed between the first protrusion and the second protrusion, and the circuit board is sandwiched between the first protrusion and the second protrusion, therefore, by the above design, the sealing performance of the cavity formed by the first protrusion, the second protrusion, the third protrusion, the fourth protrusion and the side surface of the housing can be improved, thereby better avoiding the leakage of electromagnetic waves generated by components in the circuit board.

Optionally, when the height of the second protrusion is the same as the height of the fourth protrusion, the height of the third protrusion is greater than the height of the first protrusion, and the height difference between the third protrusion and the first protrusion is equal to the thickness of the circuit board. Because a circuit board needs to be disposed between the first protrusion and the second protrusion, and the circuit board is sandwiched between the first protrusion and the second protrusion, therefore, by the above design, the sealing performance of the cavity formed by the first protrusion, the second protrusion, the third protrusion, the fourth protrusion and the side surface of the housing can be improved, thereby better avoiding the leakage of electromagnetic waves generated by components in the circuit board.

It should be noted that the upper housing shown in FIG. 7 is described in which the first area of the circuit board is located at a position of the edge area of the circuit board. When the first area is located in the intermediate area of the circuit board, the position and shape of the second protrusion 172 in the lower housing 112 are also changed accordingly so that the second protrusion 172 and the first metal strip are attached.

The optical module according to the embodiments of the present disclosure includes: a housing, a circuit board, an indicator light, and a laser driving chip, where the circuit board is disposed inside the housing, and light emitted by the indicator light can propagate to the outside of the housing; where the circuit board includes a first area, a second area and a metal strip, the metal strip encloses the first area to isolate the first area from the second area, the first area is configured to supply power to the indicator light, and the second area is electrically connected to the laser driving chip; where the housing includes a first portion, a second portion, and protrusions, the protrusions enclose the first portion to isolate the first portion from the second portion, and the protrusions and the metal strip are attached. When the protrusions and the metal strip are attached, the side walls, the protrusions of the housing and the metal strip can form two isolated cavities so that the first area of the circuit board is located in one cavity and the second area of the circuit board is located in another cavity so that the first area and the second area of the circuit board are isolated from each other, thus avoiding the second area to connect to the light outlet on the housing, and avoiding electromagnetic waves generated by components in the second area (for example, a laser driving chip, a gold finger, and the like) to leak to the outside of the housing through the light outlet on the housing, and avoiding electromagnetic waves generated by components in the second area to cause interference on other nearby electronic devices, thereby improving the safety performance of the optical module.

Hereinafter, the manner in which the circuit board is disposed in the upper housing is described with reference to the embodiment shown in FIG. 8.

FIG. 8 is a schematic structural diagram of an upper housing and a circuit board according to some embodiments of the present disclosure. Referring to FIG. 8, the circuit board 12 is disposed in the upper housing 111, and the circuit board 12 covers the first protrusion in the upper housing 111 so that the first protrusion and the metal strips 123 on the lower side of the circuit board 12 are attached.

A third protrusion 181 is further disposed inside the upper housing 111, and a first notch 1811 is disposed on the third protrusion 181, and an optical fiber in the circuit board 12 can pass through the first notch 1811.

When the upper housing 111 and the lower housing 112 are fastened, the first protrusion 171 in the upper housing 111 and the first metal strip on one side of the circuit board 12 are attached. The second protrusion 172 in the lower housing 112 and the second metal strip on the other side of the circuit board 12 are attached. The third protrusion 181 in the upper housing 111 and the fourth protrusion 182 in the lower housing 112 are attached. The cavity formed by the first protrusion 171, the second protrusion 172, the third protrusion 181, the fourth protrusion 182 and the side surface of the housing 11 encloses the second area of the circuit board 12, avoiding the second area to connecting with the light outlet on the housing, thereby avoiding electromagnetic waves generated by components in the second area (for example, a laser driving chip, a gold finger, and the like) to leak to the outside of the housing through the light outlet on the housing, and avoiding electromagnetic waves generated by components in the second area to cause interference on other nearby electronic devices, thereby improving the safety performance of the optical module.

Finally, it should be noted that the above embodiments are only used to illustrate the technical solutions of the embodiments of the present disclosure, and are not limited thereto. Although the embodiments of the present disclosure are described in detail with reference to the foregoing embodiments, those skilled in the art should understood that the technical solutions described in the foregoing embodiments may be modified, or some or all of the technical features may be equivalently substituted; and these modifications or substitutions do not deviate the essence of the corresponding technical solutions from the scope of the solutions of the embodiments of the present disclosure.

What is claimed is:

1. An optical module, comprising:
a housing comprising a first portion, a second portion, and protrusions, the protrusions configured to enclose the first portion and isolate the first portion from the second portion;
a circuit board disposed inside the housing, the circuit board comprising a first area, a second area, and a metal strip attaching to the protrusions;
an indicator light configured to emit light;
a laser driving chip; and
wherein:
the first area of the circuit board is electrically connected to the indicator light to supply power to the indicator light,
the second area of the circuit board is electrically connected to the laser driving chip, and
the metal strip encloses the first area and isolates the first area from the second area.

2. The optical module according to claim 1, wherein the first area is located at an intermediate area of the circuit board, and the metal strip is in a closed curve to enclose the first area.

3. The optical module according to claim 2, wherein the first portion is located at an intermediate portion of the housing, and the protrusions are in a closed curve to enclose the first portion.

4. The optical module according to claim 1, wherein:
the first area is located at an edge area of the circuit board; and
the metal strip comprises a first end and a second end, and the first end and the second end of the metal strip are respectively connected to edges of the circuit board to enclose the first area.

5. The optical module according to claim 1, wherein:
the housing comprises an upper housing and a lower housing;
the protrusions comprise a first protrusion and a second protrusion, wherein the first protrusion is disposed on the upper housing, and the second protrusion is disposed on the lower housing;
the metal strip comprises a first metal strip and a second metal strip, wherein the first metal strip is disposed on an upper surface of the circuit board, the second metal strip is disposed on a lower surface of the circuit board; and
the first protrusion and the first metal strip are attached, and the second protrusion and the second metal strip are attached.

6. The optical module according to claim 5, wherein:
the upper housing comprises a third protrusion;
the third protrusion comprises a first notch; and
the circuit board comprises an optical fiber passing through the first notch.

7. The optical module according to claim 5, wherein:
the lower housing comprises a fourth protrusion;
the fourth protrusion comprises a second notch; and
the circuit board comprises an optical fiber passing through the second notch.

8. The optical module according to claim 1, wherein:
the optical module further comprises a light guide comprising a first end and a second end;
the indicator light is disposed in the first area; and
wherein the first end of the light guide is configured to receive the light emitted by the indicator light and extend to a light outlet of the housing at the second end of the light guide.

9. The optical module of claim 1, wherein the indicator light is disposed at a light outlet of the housing, and the indicator light is electrically connected to the first area through a conductive connector.

10. The optical module according to claim 1, wherein a shape of the protrusions projected onto the circuit board matches with a shape of the metal strip projected onto the circuit board.

11. The optical module of claim 10, wherein the first area comprises a top corner of the circuit board.
